(19) United States
(12) Patent Application Publication
(10) Pub. No.: US 2025/0370859 A1
(43) Pub. Date: Dec. 4, 2025

(54) METHOD OF OPERATION OF A MEMORY DEVICE

(71) Applicant: SK hynix Inc., Icheon-si Gyeonggi-do (KR)

(72) Inventors: Won Jae CHOI, Icheon-si Gyeonggi-do (KR); Ho Nam YOO, Icheon-si Gyeonggi-do (KR)

(73) Assignee: SK hynix Inc., Icheon-si Gyeonggi-do (KR)

(21) Appl. No.: 18/904,562

(22) Filed: Oct. 2, 2024

(30) Foreign Application Priority Data
May 31, 2024 (KR) 10-2024-0071223

(51) Int. Cl. G06F 11/10

(52) U.S. Cl. CPC G06F 11/1044

(57) ABSTRACT

A method of operation of a memory device includes changing power from an off state to an on state, transmitting, to a controller, address information for memory cells having a shorter data retention time than other memory cells, reading data stored in memory cells corresponding the address information of the memory cells having the shorter data retention time and transmitting the data to the controller, and performing a refresh operation based on the results of an error correction operation of the controller.

### CROSS-REFERENCE TO RELATED APPLICATION

The present application claims priority under 35 U.S.C. § 119(a) to Korean Patent Application No. 10-2024-0071223, filed in the Korean Intellectual Property Office on May 31, 2024, the entire contents of which application is incorporated herein by reference.

### BACKGROUND

### 1. Technical Field

Embodiments relate to an integrated circuit technology, including but not limited to a method of operation of a memory device.

### 2. Related Art

A semiconductor system including a memory device performs a boot-up operation in order to operate normally when power changes from an off state to an on state.

A semiconductor system and a memory device each utilize a boot-up operation to perform a normal operation, but the time taken to complete the boot-up operation may reduce user satisfaction.

Accordingly, research related to reducing the time taken to complete the boot-up of the semiconductor system and the memory device continues.

### SUMMARY

In an embodiment, a method of operation of a memory device may include changing power from an off state to an on state, transmitting, to a controller, address information for memory cells having a shorter data retention time than other memory cells, reading data stored in memory cells corresponding the address information of the memory cells having the shorter data retention time and transmitting the data to the controller, and performing a refresh operation based on the results of an error correction operation of the controller.

In an embodiment, a method of operation of a memory device may include changing power from an off state to an on state, identifying address information for memory cells having a shorter data retention time than other memory cells, reading data stored in the memory cells corresponding to the address information, performing an error correction operation on the read data, and performing a refresh operation based on the results of the error correction operation.

In an embodiment, a method may include identifying address information for memory cells having a shorter data retention time than other memory cells; reading data stored in the memory cells corresponding to the address information utilizing a reference voltage; adjusting a level of the reference voltage until the data have a quantity of errors within an error correction range; performing an error correction operation on the read data; and performing a refresh operation based on results of the error correction operation.

### BRIEF DESCRIPTION OF THE DRAWINGS

FIG. 1 is a diagram illustrating a semiconductor system according to an embodiment of the present disclosure.

FIG. 2 is a flowchart illustrating operation of a semiconductor system according to an embodiment of the present disclosure.

FIG. 3 is a diagram illustrating a memory device according to an embodiment of the present disclosure.

FIG. 4 is a flowchart illustrating operation of a memory device according to an embodiment of the present disclosure.

FIG. 5 and FIG. 6 are diagrams illustrating a distribution of the threshold voltages of memory cells included in the memory device according to an embodiment of the present disclosure.

### DETAILED DESCRIPTION

Embodiments according to the technical concepts of the present disclosure are described with reference to the accompanying drawings. When one element is identified as “connected” to another element, the elements may be connected directly or through an intervening element between the elements. When two elements are identified as “directly connected,” one element is directly connected to the other element without an intervening element between the two elements.

Embodiments of the present disclosure provide a method of operation of a memory device that reduces the time taken to complete a boot-up operation.

User satisfaction may be improved by reducing the time taken to complete a boot-up operation.

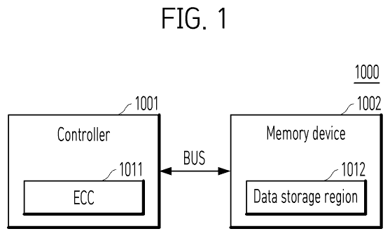

FIG. 1 is a diagram illustrating a semiconductor system according to an embodiment of the present disclosure.

Referring to FIG. 1, a semiconductor system 1000 according to an embodiment of the present disclosure includes a controller 1001 and at least one memory device 1002.

The controller 1001 and the memory device 1002 are electrically connected through a bus. For example, the controller 1001 controls the memory device 1002 through the bus. In this example, the controller 1001 provides a command, an address, and data to the memory device 1002 through the bus. The bus includes a command address bus and a data bus, for example. The command and the address are transmitted and received through the command address bus. The data are transmitted and received through the data bus. The memory device 1002 stores received data based on the command and the address provided by the controller 1001. The memory device 1002 provides the controller 1001 with data stored in the memory device based on the command and the address.

In an embodiment, the controller 1001 includes an error correction circuit 1011. In this example, the error correction circuit 1011 may be implemented with an error correction code (ECC) circuit. The error correction circuit 1011 corrects one or more errors within data received from the memory device 1002. In this example, the error correction circuit 1011 has an error correction range over which a quantity of errors within the data can be corrected, and corrects one or more errors within received data within the error correction range. The error correction circuit 1011 outputs information indicating that errors within received data cannot be corrected when the quantity of errors within the received data is greater than the error correction range. The error correction circuit 1011 outputs information indicating that the quantity of errors is greater than the error correction range when the quantity of errors within the received data is greater than the error correction range. The error correction range may be varied or changed.

In an embodiment, the memory device 1002 includes a data storage region 1012. The data storage region 1012 is a region in which data received from the controller 1001 are stored. The data storage region 1012 includes a specific region in which state information of the memory device 1002, which is utilized after the start of a boot-up operation, is stored, for example. For example, the state information of the memory device 1002, which is utilized after the start of a boot-up operation, includes address information for memory cells in which a defect occurred. As an embodiment, the memory device 1002 includes the data storage region 1012 including a specific region in which address information for memory cells in which a defect occurred while performing a test is stored. In this example, the specific region included in the data storage region 1012 is a content addressable memory (CAM) region, for example.

In an embodiment, the data storage region 1012 includes a plurality of memory blocks including a plurality of memory cells. The memory cell includes a volatile memory cell or a nonvolatile memory cell, for example. In this example, at least one of the plurality of memory blocks is a specific region in which address information for memory cells in which a defect occurred is stored.

When memory cells included in the data storage region 1012 are nonvolatile memory cells, a test may be performed during a given time period to determine whether the nonvolatile memory cells retain data stored in the nonvolatile memory cells in the state in which power is off. Such a test may be performed while varying temperature. In this example, memory cells may be detected that retain data stored in the memory cells during the given period in the state in which power is off, but have a shorter data retention time than other memory cells.

The memory device 1002 of the semiconductor system 1000 according to an embodiment of the present disclosure, stores, as memory state information, address information for memory cells having a shorter data retention time than other memory cells in a specific region of the data storage region 1012 in addition to address information for a memory cell in which a defect occurs after the start of a test.

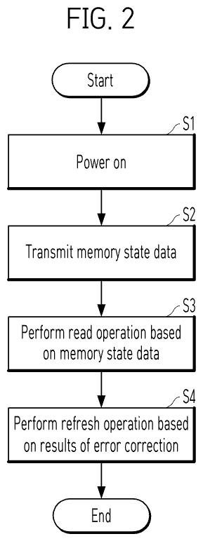

FIG. 2 is a flowchart illustrating operation of the semiconductor system according to an embodiment of the present disclosure. FIG. 2 is a flowchart illustrating a boot-up operation of the semiconductor system according to an embodiment of the present disclosure.

Referring to FIG. 2, a method of operation of the semiconductor system 1000 according to an embodiment of the present disclosure includes a power-on process S1, a memory state data transmission process S2, a read operation execution process S3, and a refresh operation execution process S4.

In an embodiment, the power-on process S1 is a process including applying power to the semiconductor system 1000 from the state in which power is off.

In an embodiment, the memory state data transmission process S2 is a process including transmitting to the controller 1001, by the memory device 1002, data including memory state information stored in a specific region of the data storage region 1012. The memory state data transmission process S2 may be performed after the controller 101 transmits, to the memory device 1002, a request to transmit data stored in a specific region of the data storage region 1012. In this example, the data stored in the specific region are data including memory state information and includes address information for memory cells detected after the start of a test. For example, the memory cells detected after the start of the test are memory cells having a shorter data retention time than other memory cells. For example, the memory state information is utilized during a boot-up operation.

In an embodiment, the read operation execution process S3 is a process including reading memory cells at locations designated by addresses received from the controller 1001. For example, the read operation execution process S3 is a process including transmitting, to the controller 1001, data stored in memory cells at locations designated by addresses received from the controller 1001, such as memory cells having a short data retention time.

In an embodiment, the refresh operation process S4 is a process including performing a refresh operation on at least one memory block including the memory cells having a short data retention time. For example, the refresh operation process S4 is a process performed when the quantity of errors within the data transmitted to the controller 1001 during the read operation execution process S3 is greater than an error correction range over which one or more errors can be corrected by the error correction circuit 1011 of the controller 1001. The refresh operation process S4 is a process performed when the quantity of errors within the data transmitted to the controller 1001 in the read operation execution process S3 is greater than an error correction range. In this example, the refresh operation is an operation including storing data stored in a memory block, referred to as a refresh target, in another or a different memory block and storing or returning the data to the original memory block after error correction. A reference voltage is used to determine data read from the memory block that is the refresh target. When the data of the memory block that is the refresh target are stored in another or different memory block, the level of the reference voltage is adjusted until the data have a quantity of errors within the error correction range correctable by the error correction circuit 1011. After the data of the memory block that is the refresh target are stored in another or a different memory block, data for which one or more errors are corrected by the error correction circuit 1011 are stored in the different memory block and stored in or returned to the original memory block after correction. Accordingly, the memory block on which the refresh operation is performed can store data without an error.

A method of operation of the semiconductor system according to an embodiment of the present disclosure is described.

When power changes from the off state to the on state, a boot-up operation of the semiconductor system is started.

The controller 1001 requests data including memory state information from the memory device 1002.

The memory device 1002 provides the controller 1001 with data stored in a specific region of the data storage region 1012 and data that include the memory state information.

The controller 1001 requests a read operation for address information for memory cells having a short data retention time, including the memory state information from the memory device 1002. In this example, the memory cells having a short data retention time are memory cells detected, for example, through a test as described.

The memory device 1002 provides the controller 1001 with data stored in memory cells at locations designated by addresses received from the controller 1001.

The controller 1001 performs an error correction operation on the received data.

When the quantity of errors within the data received from the memory device 1002 is greater than an error correction range of the error correction circuit 1011, the controller 1001 requests, from the memory device 1002, a refresh operation for a memory block including memory cells in which the data are stored having a quantity of errors greater than the error correction range.

During the method of operation of the semiconductor system 1000 including the memory device 1002 and the controller 1001 according to an embodiment of the present disclosure, an error correction operation is performed on data stored in memory cells having a shorter data retention time than other memory cells after the start of a boot-up operation, and a refresh operation is performed on a memory block including the memory cells having a short data retention time based on results of execution of the error correction operation.

The semiconductor system according to an embodiment of the present disclosure can reduce the time taken to complete a boot-up operation and may improve the reliability of data storage because an error correction operation is not performed on all of memory blocks included in the memory device after the start of or during the boot-up operation.

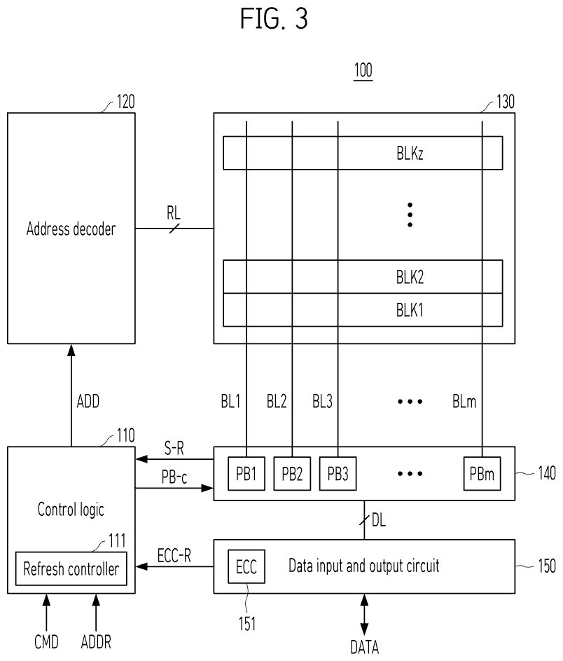

FIG. 3 is a diagram illustrating a memory device according to an embodiment of the present disclosure.

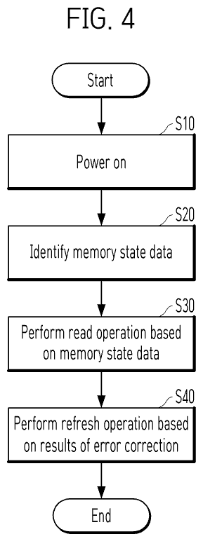

FIG. 1 and FIG. 2 are diagrams illustrating an example in which the error correction circuit 1011 is included in the controller 1001. FIG. 3 and FIG. 4 are diagrams illustrating an example in which an error correction circuit 151 is included in the memory device 100.

Referring to FIG. 3, a memory device 100 including the error correction circuit 151 according to an embodiment of the present disclosure includes control logic 110, an address decoder 120, a data storage region 130, a page buffer group 140, and a data input and output circuit 150.

The control logic 110 stores data DATA in the data storage region 130 or outputs data stored in the data storage region 130 by controlling the address decoder 120, the page buffer group 140, and the data input and output circuit 150 based on a command CMD and an address ADDR received from a controller (not illustrated). In an embodiment, the control logic 110 generates a row address ADD and a page buffer control signal PB-c, based on the command CMD and the address ADDR. The control logic 110 controls the address decoder 120 by providing the row address ADD to the address decoder 120. The control logic 110 controls the page buffer group 140 by providing the page buffer control signal PB-c to the page buffer group 140. The control logic 110 controls the address decoder 120 and the page buffer group 140 by generating the row address ADD and the page buffer control signal PB-c based on a sensing result signal S-R of the page buffer group 140 and an error correction result signal ECC-R of the error correction circuit 151. In this example, a refresh controller 111 included in the control logic 110 generates the row address ADD and the page buffer control signal PB-c based on the sensing result signal S-R of the page buffer group 140 and the error correction result signal ECC-R of the error correction circuit 151.

The address decoder 120 selectively drives row lines RL based on the row address ADD. In this example, the row lines RL include a plurality of drain selection lines, a plurality of word lines, and a plurality of source selection lines.

The data storage region 130 includes a plurality of memory blocks BLK1 to BLKz, for example. Each of the plurality of memory blocks BLK1 to BLKz includes a plurality of memory cells, for example. For example, the data storage region 130 stores data in designated memory cells of a memory block selected by the row lines RL and column lines, for example, bit lines BL1 to BLm. z and m are positive integers. The data storage region 130 transmits, to the page buffer group 140, data stored in the designated memory cells of the memory block selected by the row lines RL and the column lines BL1 to BLm through the column lines BL1 to BLm. In an embodiment, each of the plurality of memory blocks BLK1 to BLKz included in the data storage region 130 includes a plurality of memory strings. Each of the plurality of memory strings includes a plurality of memory cells, for example. The plurality of memory strings are connected between a source line and the column lines BL1 to BLm. Each of the plurality of memory strings may be constructed such that at least one drain selection transistor, a plurality of memory cell transistors, and at least one source selection transistor are connected in series. A drain selection line, among the row lines RL, is connected to the at least one drain selection transistor. A plurality of word lines is connected to the plurality of memory cell transistors, respectively. A source selection line is connected to at least one source selection transistor.

The page buffer group 140 includes a plurality of page buffers PB1 to PBm that operate based on the page buffer control signal PB-c, for example. The page buffers PB1 to PBm are connected to the column lines BL1 to BLm, respectively. The page buffers PB1 to PBm each sense selected memory cells through the column lines BL1 to BLm connected to the page buffers PB1 to PBm. In this example, the page buffer group 140 provides the control logic 110 with results of sensing of the selected memory cells as the sensing result signal S-R. The plurality of page buffers PB1 to PBm store data received from the data input and output circuit 150 and control the voltage levels of the column lines BL1 to BLm based on the stored data.

The data input and output circuit 150 transmits and receives the data DATA to and from the page buffer group 140 through a data line DL. The data input and output circuit 150 includes the error correction circuit 151. In an embodiment, the data input and output circuit 150 receives results of sensing of a selected memory cell from the page buffer group 140 through the data line DL and outputs the received results of the sensing to a device outside of the memory device 100 as the data DATA. In this example, the error correction circuit 151 performs an error correction operation on the received results of the sensing. For example, when the quantity of errors within the received results of the sensing is within an error correction range, the error correction circuit 151 corrects one or more errors. For example, when the quantity of errors within the received results of the sensing is greater than the error correction range, the error correction circuit 151 generates the error correction result signal ECC-R and transmits the error correction result signal ECC-R to the control logic 110. The data input and output circuit 150 transmits the data DATA received from the device outside of the memory device 100, to the page buffer group 140, through the data line DL. In this example, the data DATA received from the device outside of the memory device 100 are stored in each of the page buffers PB1 to PBm of the page buffer group 140, for example.

The memory device 100 constructed as described detects a defect by performing a test and corrects the detected defect. Due to defects in the memory device, errors may occur in the data output from the memory device or in the data stored in the memory device.

When memory cells included in the data storage region 130 of the memory device 100 are nonvolatile memory cells, a test may be performed during a given time period to determine whether the nonvolatile memory cells retain data stored in the nonvolatile memory cells in the state in which power is off. Such a test may be performed while varying temperature. In this example, memory cells may be detected that retain data stored in the memory cells during the given period in the state in which power is off, but have a shorter data retention time than other memory cells.

The memory device 100 according to an embodiment of the present disclosure stores, as memory state information, address information for memory cells having a shorter data retention time than other memory cells in a specific region of the data storage region 130 in addition to address information for a memory cell in which a defect occurs after the start of a test.

FIG. 4 is a flowchart illustrating operation of the memory device according to an embodiment of the present disclosure. FIG. 4 is a flowchart illustrating a boot-up operation of the memory device including the error correction circuit according to an embodiment of the present disclosure.

Referring to FIG. 4, a method of operation of the memory device 100 according to an embodiment of the present disclosure includes a power-on process S10, a memory state data identification process S20, a read operation execution process S30, and a refresh operation execution process S40.

The power-on process S10 is a process including applying power to the memory device 100 from the state in which power is off, for example.

The memory state data identification process S20 is a process including identifying memory state information stored in a specific region of the data storage region 130, for example. In an embodiment, the memory state data identification process S20 is a process including transmitting, by the address decoder 130 and the page buffer group 140, memory state information stored in a specific region of the data storage region 130 to the control logic 110 under the control of the control logic 110. In this example, data stored in the specific region are data including the memory state information and include address information for memory cells detected after the start of a test. For example, memory cells detected after the start of a test are memory cells having a shorter data retention time than other memory cells.

The read operation execution process S30 is a process including reading data included in the memory state information and stored in memory cells having a short data retention time. For example, the read operation execution process S30 is a process including transmitting, by the address decoder 130 and the page buffer group 140, data stored in memory cells having a short data retention time to the data input and output circuit 150 under the control of the control logic 110.

The refresh operation process S40 is a process including performing a refresh operation on at least one memory block including the memory cells having a short data retention time. In an embodiment, the refresh operation process S40 is a process performed when the quantity of errors within the data transmitted to the data input and output circuit 150 during the read operation execution process S30 is greater than an error correction range of the error correction circuit 151. An error correction operation is performed on the data transmitted to the data input and output circuit 150, for which data sensed from the memory cells have a shorter data retention time. When the quantity of errors of the sensed data is greater than the error correction range of the error correction circuit 151, the error correction result signal ECC-R is provided to the control logic 110. A refresh operation is performed by the refresh controller 111 of the control logic 110. In this example, the refresh operation is an operation including storing data stored in a memory block that is a refresh target in another or a different memory block and storing or returning the data to the original memory block after error correction. A reference voltage is used to determine data read from the memory block that is the refresh target. When the data of the memory block that is a refresh target are stored in another or different memory block, the level of the reference voltage is adjusted until the data have a quantity of errors within the error correction range correctable by the error correction circuit 151. After the data of the memory block that is a refresh target are stored in another or different memory block, data for which one or more errors are corrected by the error correction circuit 151 are stored in the different memory block and stored in or returned to the original memory block after correction. Accordingly, the memory block on which the refresh operation is performed can store data without an error.

A method of operation of the memory device according to an embodiment of the present disclosure is described.

A boot-up operation of the memory device 100 is started when power changes from the off state to the on state.

For example, the control logic 110 controls a read operation to be performed on data stored in memory cells having a short data retention time by identifying data stored in a specific region of the data storage region 130 and that include memory state information.

The error correction circuit 151 of the data input and output circuit 150 performs an error correction operation on the data received by the read operation.

When the quantity of errors within the data received by the data input and output circuit 150 is greater than an error correction range of the error correction circuit 151, the error correction circuit 151 transmits the error correction result signal ECC-R to the control logic 110. The refresh controller 111 of the control logic 110 performs a refresh operation on a memory block including memory cells in which the data are stored having a quantity of errors greater than the error correction range.

During the method of operation of the memory device 100 according to an embodiment of the present disclosure, an error correction operation is performed on data stored in memory cells having a shorter data retention time than other memory cells after the start of a boot-up operation, and a refresh operation is performed on a memory block including the memory cells having a short data retention time based on results of execution of the error correction operation.

The memory device 100 according to an embodiment of the present disclosure can reduce the time taken to complete a boot-up operation and may improve the reliability of data storage because an error correction operation is not performed on all of memory blocks included in the data storage region 130 after the start of or during the boot-up operation.

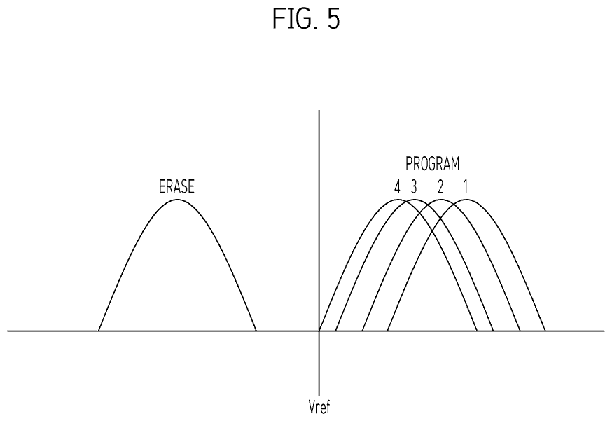

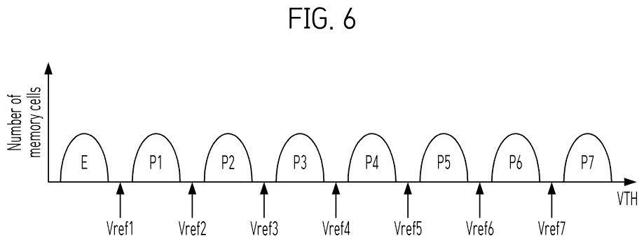

FIG. 5 and FIG. 6 are diagrams illustrating a distribution of the threshold voltages of memory cells included in the memory device according to an embodiment of the present disclosure. FIG. 5 is a diagram illustrating a retention issue for a distribution of the threshold voltages of nonvolatile memory cells.

Referring to FIG. 5, the nonvolatile memory cells have an erase state ERASE in which a distribution of the threshold voltages is low or a program state PROGRAM in which a distribution of the threshold voltages is high, for example. In this example, the distribution of the threshold voltages of the nonvolatile memory cells in the program state has lower voltage levels over time, for example (1→2→3→4). Such a condition is referred to as a retention issue. The retention issue may accelerate or increase as temperature rises.

To distinguish between the erase state and the program state of the nonvolatile memory cells, a reference voltage Vref is used, for example. The reference voltage Vref may be at a middle level between an erase state and a normal program state (1).

As time elapses during the state in which power is off, the threshold voltage of the nonvolatile memory cells in the program state may gradually lower. One or more errors may occur in the nonvolatile memory cell during the program state when the level of the threshold voltage is lower than the level of the reference voltage.

In order to correct the one or more errors, during the method of operation of the semiconductor system 1000 and the memory device 100 according to an embodiment of the present disclosure, for example during a boot-up operation, address information of nonvolatile memory cells having a short data retention time after the start of a test is stored, and a refresh operation is performed on the nonvolatile memory cells corresponding to the stored address information by performing a read operation and an error correction operation on the nonvolatile memory cells. The time taken to complete a boot-up operation can be reduced, and the reliability of data storage may be improved. For example, the refresh operation is an operation including lowering the level of the reference voltage Vref to reduce the quantity of errors to a value within an error correction range over which the error correction operation can be performed.

Referring to FIG. 6, nonvolatile memory cells have an erase state E in which the levels of the threshold voltages of the nonvolatile memory cells are the lowest and a first program state P1, a second program state P2, a third program state P3, a fourth program state P4, a fifth program state P5, a sixth program state P6, and a seventh program state P7 in which the levels of the threshold voltages of the nonvolatile memory cells gradually rise. A first reference voltage Vref1 is a voltage used to distinguish between the erase state E and the first program state P1. A second reference voltage Vref2 is a voltage used to distinguish between the first program state P1 and the second program state P2. A third reference voltage Vref3 is a voltage used to distinguish between the second program state P2 and the third program state P3. A fourth reference voltage Vref4 is a voltage used to distinguish between the third program state P3 and the fourth program state P4. A fifth reference voltage Vref5 is a voltage used to distinguish between the fourth program state P4 and the fifth program state P5. A sixth reference voltage Vref6 is a voltage used to distinguishes between the fifth program state P5 and the sixth program state P6. A seventh reference voltage Vref7 is a voltage used to distinguish between the sixth program state P6 and the seventh program state P7.

A retention issue most likely occurs in a nonvolatile memory cell during the state in which the threshold voltage of the nonvolatile memory cell is high. For example, when nonvolatile memory cells having a short data retention time are detected after the start of a test, the nonvolatile memory cells are programmed to the seventh program state.

The levels of the threshold voltages of nonvolatile memory cells in which the multiple levels illustrated in FIG. 6 are stored during the program states P1, P2, P3, P4, P5, P6, and P7, may be gradually lowered over time during the state in which power is off. One or more errors may occur in a nonvolatile memory cell during the program state when the level of a threshold voltage is lower than the level of each of the first reference voltage to the seventh reference voltage.

During a method of operation of the semiconductor system 1000 and the memory device 100 according to an embodiment of the present disclosure, for example during a boot-up operation, address information of nonvolatile memory cells having a short data retention time after the start of a test is stored, and a refresh operation is performed on the nonvolatile memory cells corresponding to the stored address information by performing a read operation and an error correction operation on the nonvolatile memory cells. The time taken to complete a boot-up operation can be reduced, and the reliability of data storage may be improved. For example, the refresh operation is an operation including lowering the level of each of the first to seventh reference voltages Vref1 to Vref to reduce the quantity of errors to a value within an error correction range over which the error correction operation can be performed.

Although embodiments according to the technical concepts of the present disclosure are described with reference to the accompanying drawings, the embodiments are provided to merely describe embodiments according to the concepts of the present disclosure, and the present disclosure is not limited to the embodiments. A person having ordinary knowledge in the art to which the present disclosure pertains may substitute, modify, add to, and change the embodiments in various ways without departing from the technical concepts of the present disclosure. Therefore, the scope of the present disclosure should not be limited to the foregoing embodiments. All changes within the meaning and range of equivalency of the claims are included within their scope.

What is claimed is:

1. A method of operation of a memory device, the method comprising:
changing power from an off state to an on state;
transmitting, to a controller, address information for memory cells having a shorter data retention time than other memory cells;
reading data stored in memory cells corresponding the address information of the memory cells having the shorter data retention time and transmitting the data to the controller; and
performing a refresh operation based on results of an error correction operation of the controller.

2. The method of claim 1, wherein the address information is stored in a specific region of the data storage region of the memory device.

3. The method of claim 2, wherein data stored in the specific region comprise information generated based on results of a test.

4. The method of claim 1, wherein transmitting the address information to the controller is performed when the controller requests, from a memory device, information utilized during a boot-up operation.

5. The method of claim 1, wherein performing the refresh operation comprises performing the refresh operation when a quantity of errors within the data received by the controller is greater than an error correction range over which the controller performs the error correction operation.

6. The method of claim 5, wherein performing the refresh operation comprises performing the refresh operation on a memory block comprising memory cells in which the data are stored having the quantity of errors greater than the error correction range.

7. The method of claim 6, wherein performing the refresh operation comprises:
adjusting a level of a reference voltage that distinguishes between states of the memory cells until the quantity of errors within the data of the memory block is reduced to a value within the error correction range;
storing the data of the memory block in a different memory block in relation to the reference voltage; and
returning the data stored in the different memory block to the memory block.

8. A method of operation of a memory device, the method comprising:
changing power from an off state to an on state;
identifying address information for memory cells having a shorter data retention time than other memory cells;
reading data stored in the memory cells corresponding to the address information;
performing an error correction operation on the read data; and
performing a refresh operation based on results of the error correction operation.

9. The method of claim 8, wherein the address information is stored in a specific region of a data storage region of a memory device.

10. The method of claim 9, wherein data stored in the specific region comprise information generated based on results of a test.

11. The method of claim 8, wherein identifying the address information comprises identifying, by control logic of the memory device, the data stored in the specific region after start of a boot-up operation.

12. The method of claim 8, wherein the refresh operation is performed when a quantity of errors of the read data is greater than an error correction range of the error correction operation.

13. The method of claim 12, wherein performing the refresh operation comprises performing the refresh operation on a memory block comprising memory cells in which the data are stored having the quantity of errors greater than the error correction range.

14. The method of claim 13, wherein performing the refresh operation comprises:
adjusting a level of a reference voltage that distinguishes between states of the memory cells until the quantity of errors within the data of the memory block is reduced to a value within the error correction range;
storing the data of the memory block in a different memory block in relation to the reference voltage; and
returning, to the memory block, the data stored in the different memory block.
